(19) United States
(12) Patent Application Publication
(10) Pub. No.: US 2009/0051447 A1
(43) Pub. Date: Feb. 26, 2009

(54) Ovenized oscillator

(76) Inventors: Jeffrey A. McCracken, Sugar Grove, IL (US); Thomas A. Knecht, Dundee, IL (US)

Correspondence Address: DANIEL J. DENEUFBOURG;CTS CORPORATION, 171 COVINGTON DRIVE, BLOOMINGDALE, IL, 60108, US

(21) Appl. No.: 12/229,113

(22) Filed: Aug. 20, 2008

Related U.S. Application Data
(63) Continuation-in-part of application No. 12/075,589, filed on Mar. 12, 2008.
(60) Provisional application No. 60/966,083, filed on Aug. 24, 2007.

(51) Int. Cl. H03L 1/04

(52) U.S. Cl. 331/70

(57) ABSTRACT

An ovenized oscillator package including a ball grid array substrate seated on a circuit board, a heater and a temperature sensor mounted on the ball grid array substrate, and a crystal package mounted to the ball grid array substrate and overlying at least the heater. A layer of thermally conductive epoxy or adhesive material couples the heater to the crystal package. Stabilizer posts, which are made of an insulative adhesive or epoxy material, are formed between the ball grid array substrate and the circuit board for stabilizing and relieving the stress on the ball grid array substrate. A lid is seated on the circuit board and covers and defines an oven for the ball grid array substrate.

### CROSS-REFERENCE TO RELATED AND CO-PENDING APPLICATIONS

This application is a continuation-in-part application of U.S. patent application Ser. No. 12/075,589 filed on Mar. 12, 2008, and titled “Apparatus and Method for Temperature Compensating an Ovenized Oscillator”.

This application also claims the benefit of the filing date of U.S. Provisional Patent Application Ser. No. 60/966,083 filed on Aug. 24, 2007, the disclosures of which are explicitly incorporated herein by reference as are all references cited therein.

### FIELD OF THE INVENTION

This invention relates generally to oscillators that can provide a stable reference frequency signal in electronic equipment and, more specifically, to an oscillator that is contained within a heated enclosure.

### DESCRIPTION OF THE RELATED ART

Various devices are known for providing a reference frequency or source. Such devices are called oscillators. The oscillator typically includes at least a quartz crystal or other resonator and electronic compensation circuitry adapted to stabilize the output frequency.

Ovenized oscillators (OCXO) heat the temperature-sensitive portions of the oscillator, which are isolated from the ambient temperature, to a uniform temperature to obtain a more stable output. Ovenized oscillators contain a heater, a temperature sensor, and circuitry to control the heater. The temperature control circuitry holds the crystal and critical circuitry at a precise, constant temperature. The best controllers are proportional, providing a steady heating current which changes with the ambient temperature to hold the oven at a precise set-point, usually about 10 degrees above the highest expected ambient temperature.

The present invention is directed to the continued need for the effective transfer of heat between the heater and the crystal.

### SUMMARY OF THE INVENTION

The present invention is directed to an oscillator assembly or package which comprises a circuit board, a ball grid array substrate seated on the circuit board, a heater and a temperature sensor seated on the ball grid array substrate, and a crystal package suspended over the heater and the temperature sensor.

In accordance with the invention, a layer of thermally conductive epoxy or adhesive couples at least the heater to the crystal package and a plurality of insulative posts made of epoxy or adhesive material are located between the ball grid array substrate and the circuit board for stabilizing the ball grid array substrate on the circuit board.

There are other advantages and features of this invention, which will be more readily apparent from the following detailed description of the embodiments of the invention, the drawings, and the appended claims.

### BRIEF DESCRIPTION OF THE DRAWINGS

These and other features of the invention can best be understood by the following description of the accompanying drawings as follows:

FIG. 1 is a block diagram of an ovenized oscillator in accordance with the present invention;

FIG. 2 is a top perspective view of a physical embodiment of an oscillator package incorporating the features of FIG. 1;

FIG. 3 is a bottom perspective view of the oscillator package of FIG. 2;

FIG. 4 is a part side elevational view, part vertical cross-sectional view of the interior of the oscillator package of FIG. 2; and

FIG. 5 is a top plan view of the oscillator package of FIG. 2 without the cover.

### DETAILED DESCRIPTION OF THE EMBODIMENTS

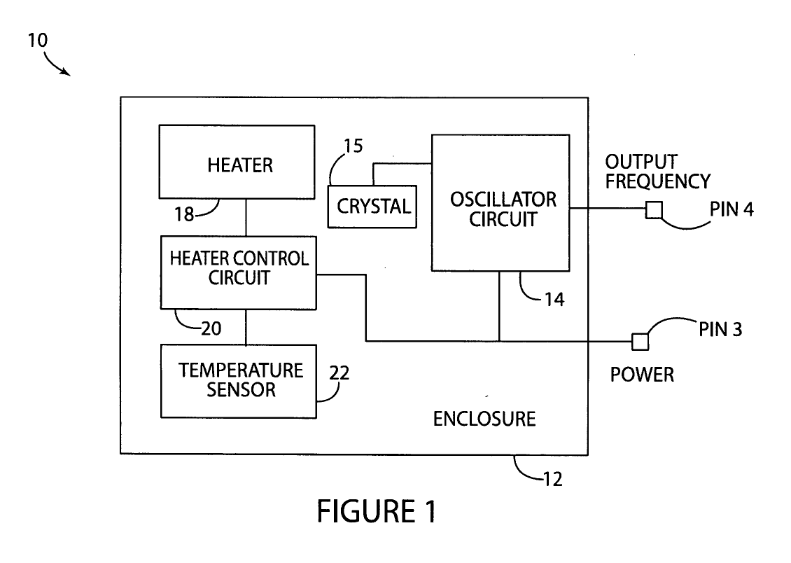

A diagrammatic view/block diagram of an ovenized oscillator (OCXO) 10 in accordance with the present invention is shown in FIG. 1. Ovenized oscillator 10 includes an enclosure, housing, or oven 12 which houses and contains the oscillator components. Oven 12 can be an enclosure with or without insulation. A conventional crystal oscillator circuit 14, which is in communication with a resonator or crystal 15, is located in oven 12. Oscillator circuit 14 can be a Colpitts oscillator circuit using a quartz crystal. Oscillator circuit 14 provides a stable reference frequency at output terminal PIN 4. PIN 3 is a 3.3 volt power supply terminal.

A heater 18 is located in oven 12. Heater 18 is typically a transistor in which the dissipated power is proportionally controlled to heat and maintain a specified temperature level inside the oven 12. A temperature sensor 22 is located in proximity to cover 12. Sensor 22 can be a negative coefficient conventional thermistor adapted to measure the temperature of the crystal. Connected to sensor 22 and heater 18 is a heater control circuit 20 which controls heater 18.

Control circuit 20 receives a temperature signal as an input from sensor 22 and provides a heater control signal as an output. When the temperature is below a selected value for the oven, heater control circuit 20 increases the power to heater 18 to increase the temperature in oven 12. When the temperature is above a selected value for the oven, heater control circuit 20 reduces the power to heater 18 to allow a decrease in the temperature in oven 12.

### Oscillator Package

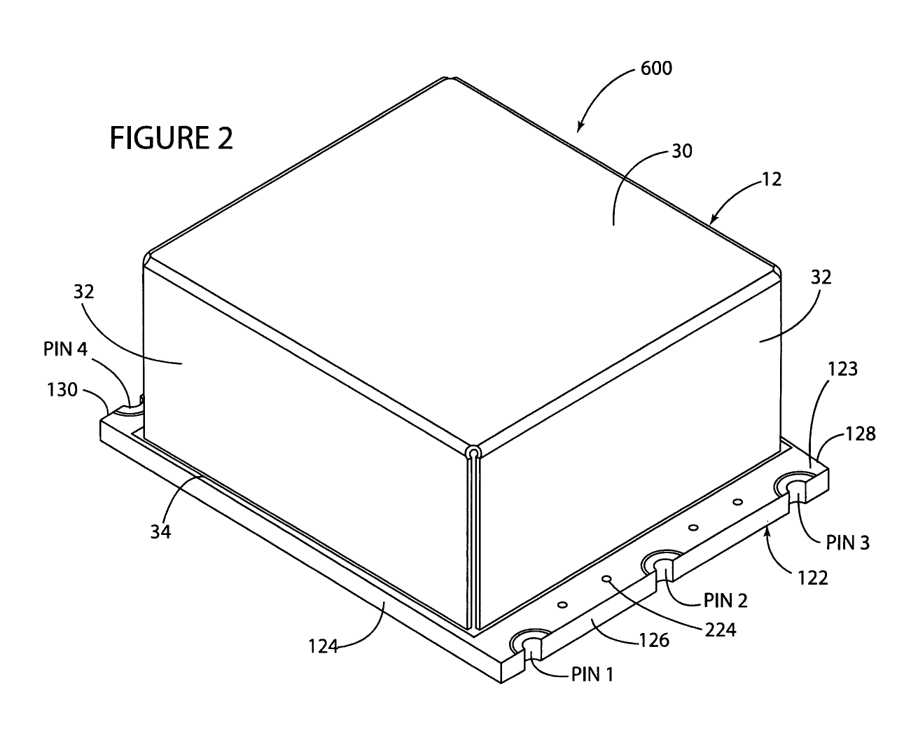

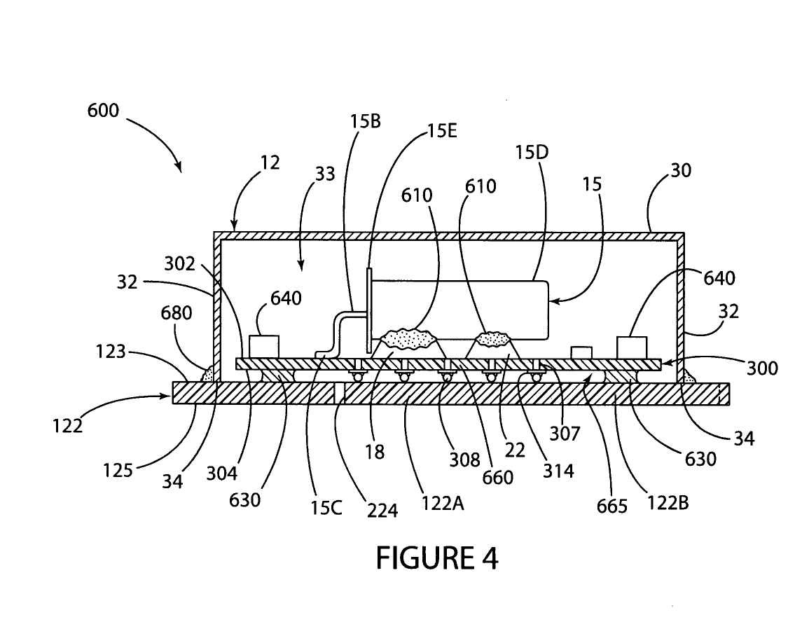

A physical embodiment of an ovenized oscillator 10 in accordance with the present invention is shown in FIGS. 2-5. Ovenized oscillator 10 can be packaged in an oscillator assembly, electronic package, or oscillator package 600. Oscillator assembly or package 600 may have an overall size of about 25 mm. in length by 22 mm. in width by 8.5 mm. in height and include a generally rectangular-shaped printed circuit board 122 including a top face 123 (FIGS. 2 and 4) on which all of the electrical and electronic components defining the oscillator are appropriately mounted and interconnected together with an enclosure, housing, lid, or cover 12 which covers all of the components.

Although not shown, it is understood that, in the embodiment shown, the printed circuit board 122 is made of a plurality of conventional electrically insulative laminates.

Housing 12 defines an interior cavity 33 (FIG. 4) and defines a top roof 30 and four downwardly-extending side walls 32 (FIGS. 2-4). Side walls 32 define respective lower peripheral end face edges 34 (FIG. 4).

Printed circuit board 122 includes respective front and back (top and bottom) faces 123 and 125 and respective elongate side peripheral end edges or faces 124, 126, 128 and 130 (FIGS. 2-4).

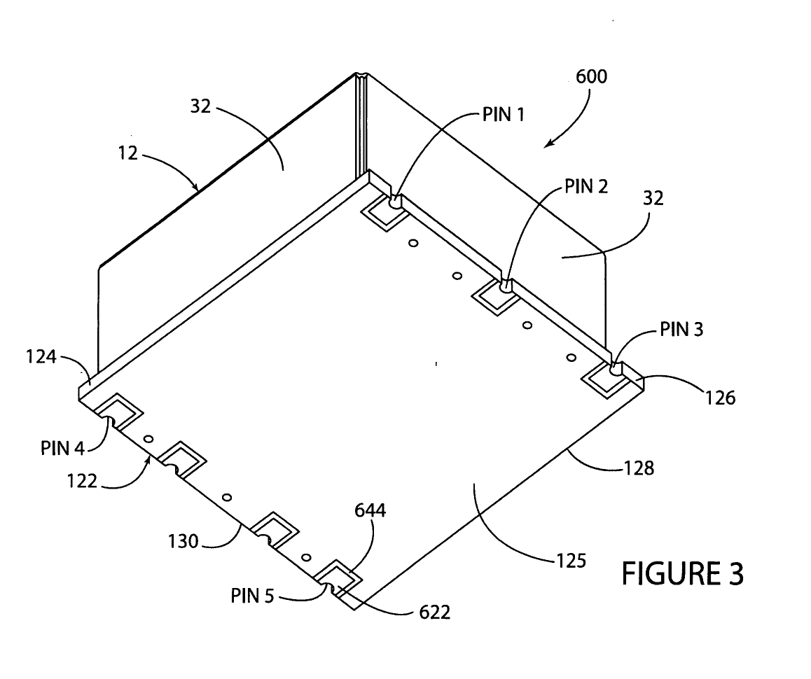

Referring to FIGS. 2 and 3, a first plurality of castellations defining direct surface mount pads or pin #s 1, 2, and 3 are formed and extend along the length of the board side edge 126 in spaced-apart and parallel relationship.

A second plurality of castellations defining at least direct surface mount pads or pin #s 4 and 5 are formed and extend along the length of, and generally at opposed ends of, the board side edge 130 in spaced-apart and parallel relationship.

Each of the castellations is defined by a generally semi-circularly-shaped elongate groove which is formed in the respective side edges; extends between the top and bottom faces 123 and 125 of the board 122 in an orientation generally normal thereto; and is covered/coated with a layer of conductive material to define a path for electrical signals between the top and bottom faces 123 and 125 of the board 122.

The castellations are adapted to be seated against the respective pads or pins of a motherboard to which the module 600 is adapted to be direct surface mounted. The castellations are electrically connected with various circuit lines and plated through-holes in circuit board 122.

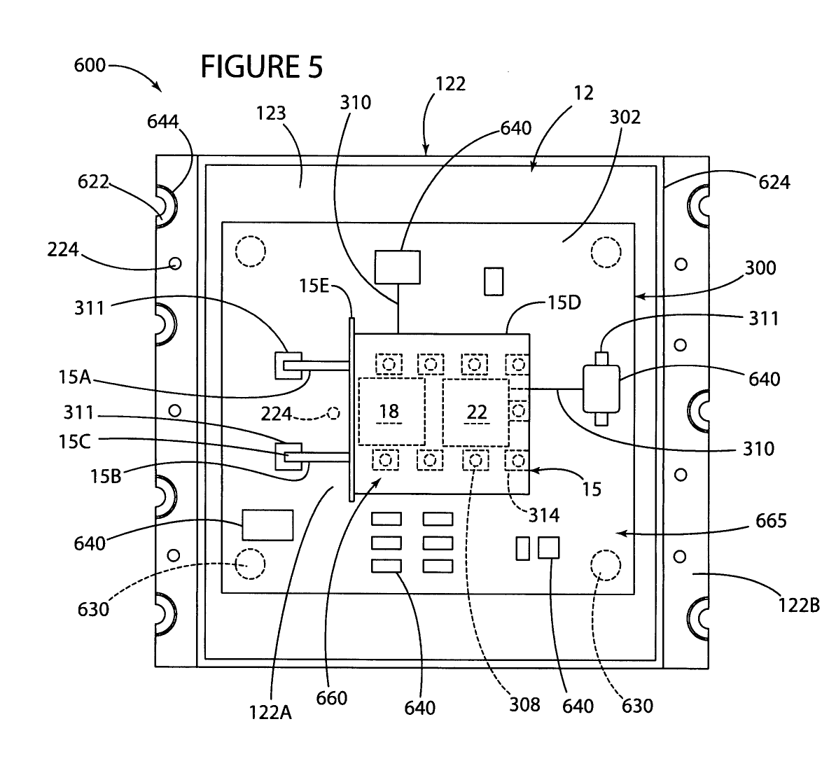

Each of the grooves defined by the non-ground castellations in the respective top and bottom faces 123 and 125 of board 122 are surrounded by a region/layer 622 of copper conductive material (FIG. 5) which, in turn, is surrounded by a region 644 (FIG. 5) which is devoid of conductive material to separate the respective input and output pins from ground.

A plurality of conductive wiring traces (not shown) which are internal to circuit board 122 can be used to interconnect the ceramic ball grid array substrate 300 (FIG. 4) to the castellations through plated through-holes 224 (FIGS. 2 and 5). Plated through-holes 224 extend through the board 122 in a relationship generally normal to the top and bottom board faces 123 and 125. The plated through-holes 224 are coated with conductive material and serve the purpose of making electrical connections between the top and bottom surfaces 123 and 125 respectively of the printed circuit board 122.

In the embodiment of FIGS. 4 and 5, oscillator assembly 600 includes a ball grid array ceramic (BGA) substrate. BGA substrate 300 includes a top surface 302 and bottom surface 304 (FIG. 4). Substrate 300 can be made of any various ceramic material such as, for example, alumina. Spaced-apart conductive balls 308 (FIGS. 4 and 5) are mounted, as by soldering or the like, to the bottom surface 304 of BGA substrate 300 and are electrically connected to the ends of respective vias 307 (FIG. 4) defined and extending through BGA substrate 300 between surfaces 302 and 304.

BGA substrate 300 is electrically and mechanically attached to, and seated on top of, the circuit board 122 as shown in FIG. 4 through the conductive balls 308 which are sandwiched between, and in contact with, the lower surface of BGA substrate 300 on one side and the upper surface of board 122 on the other side. BGA substrate 300 further defines a plurality of conductive lines 310 and pads 311 on top surface 302 (FIG. 5) and ball pads 314 (FIGS. 4 and 5) on bottom surface 304. Conductive lines 310 are adapted to make electrical connections with ball pads 314 and vias 307. Conductive balls 308 can be electrically connected to ball pads 314 through the use of a conductive material such as a solder alloy.

As shown in FIGS. 4 and 5, various electronic components 640 can be mounted to the top surface 302 of BGA substrate 300. Electronic components 640 may include resistors, capacitors, inductors, transistors, varactors, integrated circuits, diodes, heater 18, temperature sensor 22, and crystal package 15. The various electronic components can be attached to top surface 302 by soldering as known in the art.

As shown in FIG. 4, crystal package 15 is mounted to BGA substrate 300 in a relationship overlying, and seated on, both the heater 18 and temperature sensor 22. Crystal package 15 has electrical leads 15A and 15B (FIGS. 4 and 5) that extend down and are connected to pads 311 (FIG. 5) on the top surface 302 of BGA substrate 300. Crystal package 15 defines a housing or body 15D (FIGS. 4 and 5) that contains a quartz crystal and a rear lid 15E (FIGS. 4 and 5) which seals one of the side faces of the housing 15D. Crystal package 15 can contain a crystal or resonator (not shown). The electronic components can be electrically connected to pads 311 by a conductive material such as a solder alloy.

Crystal package 15 can be disposed in a relationship spaced from, and parallel to, the top surface 302 of BGA substrate 300. Heater 18 and temperature sensor 22 are located (i.e., sandwiched) in the space defined between the lower face of crystal package 15 and the top face 302 of BGA substrate 300.

A layer of thermal adhesive or epoxy 610 (FIG. 4), preferably having high heat transfer properties, is adapted to be applied between the lower face of crystal body 15D and the heater 18. Similarly, a layer of thermal adhesive or epoxy 610 is adapted to be applied between the lower face of crystal body 15D and the temperature sensor 22. Thermal epoxy 610 can facilitate heat transfer between the heater 18 and crystal 15. Thermal epoxy 610 can also facilitate heat transfer between the temperature sensor 22 and crystal 15. Thermal epoxy 610 provides a thermal path for the temperature sensor 22 to precisely monitor the temperature of crystal 15.

BGA substrate 300 has several conductive balls 308 (FIGS. 4 and 5) that are located in a central region 660 of BGA substrate 300. Conductive balls 308 are located on the lower surface of BGA substrate 300 and are electrically connected to ball pads 314 (FIGS. 4 and 5) on the top surface 123 of board 122 by a solder joint in a central region 122A (FIG. 5) of circuit board 122.

Several areas or posts of insulative adhesive or epoxy 630 (FIGS. 4 and 5) can be placed between BGA substrate bottom surface 304 and circuit board top surface 123 to position the BGA substrate 300 and board 122 in a spaced-apart and generally parallel relationship. The insulative epoxy can be placed toward outer, peripheral areas 665 (FIG. 5) of BGA substrate 300 (such as, for example, the four corners thereof) and toward an outer peripheral area 122B (FIG. 4) of circuit board 122. Insulative epoxy 630 can be a conventional polymer epoxy material.

Insulative epoxy 630 is used to attach the outer peripheral area 665 of BGA substrate 300 to the outer peripheral area 122B of circuit board 122. Insulative epoxy 630 stabilizes and supports outer peripheral area 665 of BGA substrate 300 above, and spaced from, circuit board 122.

The bottom surface 125 (FIG. 4) of circuit board 122 may be exposed to a range of temperatures. Because BGA substrate 300 is formed from a ceramic material and circuit board 122 is formed from an organic material, the differences in the coefficients of thermal expansion of BGA substrate 300 and circuit board 122 may cause stress in solder joints of conductive balls 308 that are located at the outer peripheral areas 122B and 665.

In oscillator package 600, the conductive balls 308 are mounted to the lower surface and in the central region 660 of BGA substrate 300 to minimize the stress on the solder joints. The addition of insulative epoxy posts 630 stabilizes and supports the outer peripheral area 665 of BGA substrate 300 and are used in lieu of solder joints which can cause stress due to the differences in the thermal properties of the BGA substrate 300 and the circuit board 122.

In addition, by minimizing the use of conductive balls 308 on BGA substrate 300, the heat loss from inside oven 33 to the outside environment through conductive balls 308 is reduced.

As described earlier, oscillator assembly 600 additionally comprises an outer housing, cover, lid, enclosure, or oven 12 which is made of any suitable material and is adapted to be fitted and seated over the top face 123 of the board 122 in a relationship where the lid 12 covers and surrounds the BGA substrate 300 and all of the components mounted thereto.

In one embodiment, lid 12 has sidewalls 32 that are mounted on and coupled to the top face 123 of board 122 using solder joints 680 (FIG. 4). In another embodiment, lid 12 may be formed from a plastic material and mounted to circuit board 122 using an adhesive.

The roof and walls of lid 12 may be filled with insulation if desired. Lid 12 serves the purpose of a cover and isolates the electronic components from large thermal gradients. Lid 12 is adapted to be seated over region 624 of board 122 shown in FIG. 5.

This particular arrangement and positioning of the various components defining oscillator package 600 of the present invention on printed circuit board 122 and BGA substrate 300 allows for a compact package with good noise characteristics.

### Operation

Ovenized oscillator 10 is designed to operate over a range of temperatures. When temperature sensor 22 detects that the temperature of crystal package 15 is less than a predetermined preset temperature, heater control circuit 20 turns on heater 18 to heat the crystal. Heater control circuit 20 is adapted to increase or decrease the current applied to the heater 18 in order to maintain a relatively stable temperature around the preset temperature within enclosure 12.

When temperature sensor 22 detects that the temperature of crystal package 15 is greater than the preset temperature, heater control circuit 20 reduces the current to heater 18 in order to maintain the preset temperature within enclosure 12.

With a stable temperature inside enclosure 12 provided by heater circuit 20, crystal oscillator circuit 14 is able to provide a stable reference frequency at output terminal PIN 4 regardless of the temperature outside of oven or enclosure 12.

### CONCLUSION

While the invention has been taught with specific reference to this embodiment, someone skilled in the art will recognize that changes can be made in form and detail without departing from the spirit and the scope of the invention. The described embodiment is to be considered in all respects only as illustrative and not restrictive. The scope of the invention is, therefore, indicated by the appended claims rather than by the foregoing description. All changes that come within the meaning and range of equivalency of the claims are to be embraced within their scope.

What is claimed is:

1. An oscillator assembly comprising:
a circuit board;
a ball grid array substrate seated on the circuit board and defining top and bottom surfaces;
a heater mounted on the top surface of the ball grid array substrate;
a temperature sensor mounted on the top surface of the ball grid array substrate;
a crystal package coupled to the top surface of the ball grid array substrate and overlying the heater and/or the temperature sensor;
a layer of thermally conductive material coupling the crystal package to the heater and/or the temperature sensor; and
a lid covering the ball grid array substrate.

2. The oscillator assembly according to claim 1, wherein the lid is seated on the circuit board and covers the ball grid array substrate.

3. The oscillator assembly according to claim 1, wherein conductive balls are located between the circuit board and the ball grid array substrate in a central area of the ball grid array substrate.

4. The oscillator assembly according to claim 1, wherein a plurality of stabilizer posts are formed between the ball grid array substrate and the circuit board.

5. The oscillator assembly according to claim 4, wherein the layer of thermally conductive material and the posts are made of an epoxy or adhesive material, the posts being located toward an outer peripheral area of the ball grid array substrate.

6. An oscillator assembly comprising:
a first circuit board;
a second circuit board mounted to the first circuit board;
a heater mounted to the second circuit board;
a temperature sensor mounted to the second circuit board;
a crystal package mounted to the second circuit board; and
a plurality of stabilizer posts located between the first and second circuit boards, the posts being made of an insulative material.

7. The oscillator assembly of claim 6, wherein the posts are located at the corners of the second circuit board.

8. An oscillator assembly comprising:
a circuit board;
a ball grid array substrate seated on the circuit board;
a plurality of posts made of epoxy material located between the circuit board and the ball grid array substrate and adapted to stabilize and support the ball grid array substrate on the circuit board;
a heater and a temperature sensor mounted on the ball grid array substrate;
a crystal package mounted to the ball grid array substrate and overlying the heater or the temperature sensor; and
a layer of thermally conductive material disposed between and coupling the heater and/or the temperature sensor to the crystal package.

9. The oscillator assembly of claim 8, wherein the posts are located at the respective corners of the ball grid array substrate.

10. The oscillator assembly of claim 8, wherein the thermally conductive material is an epoxy or adhesive.
